(19) United States
(12) Patent Application Publication
(10) Pub. No.: US 2006/0113662 A1
(43) Pub. Date: Jun. 1, 2006

(54) Micro heat pipe with wedge capillaries

(76) Inventor: Juan Cepeda-Rizo, Lakewood, CA (US)

Correspondence Address: Legal Department;Teradyne, Inc., 321 Harrison Avenue, Boston, MA, 02118, US

(21) Appl. No.: 10/884,306

(22) Filed: Jul. 3, 2004

(51) Int. Cl. H01L 23/34

(52) U.S. Cl. 257/714

(57) ABSTRACT

A heat pipe is disclosed comprising an elongated hollow housing having a condenser end and an evaporator end. A corrugated wick is disposed within the housing. The wick comprises a plurality of wedge-shaped capillaries extending from the condenser end to the evaporator end. A liquid is set in fluid communication with the corrugated wick.

### FIELD

The invention relates generally to passive cooling schemes, and more particularly heat pipes for cooling electronic assemblies used in automatic test equipment.

### BACKGROUND

Thermal management is a significant issue facing the electronics industry in light of ever-increasing IC component power levels and power densities. Heat pipes provide an important means of passively and inexpensively transporting heat away from an electronic component to an area more accessible to higher capacity cooling systems.

Conventional heat pipes often comprise an elongated sealed tube that houses a fluid and a wicking structure. One end of the tube, known as the evaporator, is brought into contact with a heat generating component.

Thermal conductivity between the heat generating component and the tube causes the fluid in the evaporator to vaporize, where it is forced by pressure to the opposite end of the heat pipe, referred to as the condenser.

In the condenser, the vaporized fluid condenses and releases its latent heat of vaporization. The wicking structure operates to draw the fluid back from the condenser to the evaporator. Consequently, the heat pipe thermal transport capability often depends on the wicking structure performance.

Traditional wicks used in heat pipes typically take on a variety of forms, such as triangles or grooves, to draw the fluid back to the evaporator. The angles between adjacent edges of the grooves are often set apart at relatively wide angles on the order of sixty degrees or greater in an effort to minimize any vapor flow impediments. While the conventional wick structures allegedly work well for their intended applications, the need exists for a heat pipe having improved wicking action to maximize heat transport. The heat pipe described herein satisfies this need.

### SUMMARY

The heat pipe described herein provides low cost passive cooling with enhanced heat transport ability. This enables the use of low-cost passive cooling techniques for high power and high density electronic assemblies.

To realize the foregoing advantages, the heat pipe in one form comprises a heat pipe comprising an elongated hollow housing having a condenser end and an evaporator end. A corrugated wick is disposed within the housing. The wick comprises a plurality of wedge-shaped capillaries extending from the condenser end to the evaporator end. A liquid is set in fluid communication with the corrugated wick.

In another form, the heat pipe comprises a multi-chip module assembly. The assembly includes a multi-chip module comprising a substrate and a plurality of integrated circuits disposed on the substrate, and a heat pipe assembly. The heat pipe assembly comprises a heat sink and a plurality of heat pipes disposed in thermal contact with the integrated circuits. Each heat pipe comprises an elongated hollow housing having a condenser end and an evaporator end. A corrugated wick is disposed within the housing. The wick comprises a plurality of wedge-shaped capillaries extending from the condenser end to the evaporator end. A liquid is set in fluid communication with the corrugated wick.

In a further form, the heat pipe operates in accordance with a method of directing fluid away from the condenser end of the heat pipe to an evaporator end. The method comprises the step of wicking the fluid from the condenser to the evaporator over a plurality of pleated fins having respective wicking angles within the range of ten to fifteen degrees.

Other features and advantages of the present invention will be apparent from the following detailed description when read in conjunction with the accompanying drawings.

### BRIEF DESCRIPTION OF THE DRAWINGS

The heat pipe described herein will be better understood by reference to the following more detailed description and accompanying drawings in which

FIG. 1 is a partial perspective view of a heat pipe in accordance with the description provided herein;

FIGS. 2a and 2b are partial perspective views of alternative corrugated wicking structures;

FIG. 3 is a flow chart of a method of fabricating the heat pipe of FIG. 1; and

FIG. 4 is an exploded view of a multi-chip module assembly that employs a plurality of heat pipes shown in FIG. 1.

### DETAILED DESCRIPTION

The heat pipe described herein provides enhanced cooling capability by employing a wicking structure that operates according to “wedge capillary” theory. This allows for the use of heat pipes in high-power density cooling applications to minimize cooling costs.

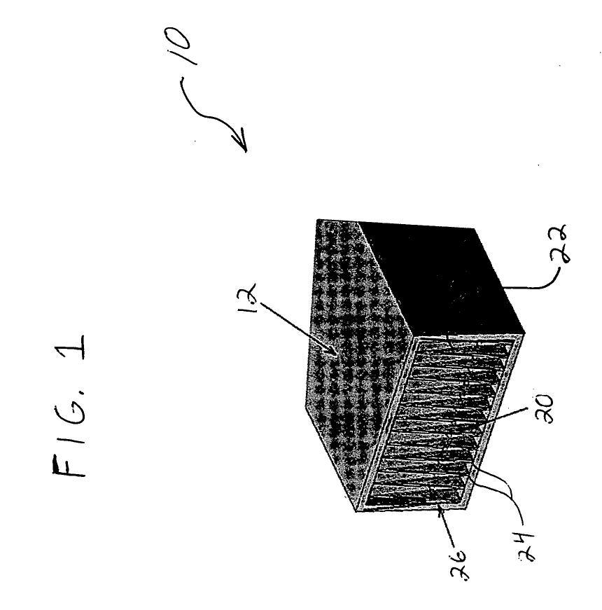

Referring now to FIG. 1, the heat pipe, generally designated 10, includes an elongated hollow housing 12 having a rectangular cross-section. The relative dimensions of the housing generally depend on the specific application involved, but may range from one to twelve inches in length, 0.25 to 0.5 inches in width, and from 0.1 to 0.25 inches in height. Preferably, the housing is formed from a thermally conductive metal such as copper.

With further reference to FIG. 1, disposed within the housing is a corrugated wick 20. The wick is formed from a thin pleated copper sheet on the order of from 0.005 inches to 0.008 inches thick to define a plurality of wedge-shaped capillaries. The capillaries extend longitudinally along the entire length of the housing 12 and comprise folded fins 22 joined together at adjacent edges 24 to form narrow vertices defining an angle φ within the range of between five to fifteen degrees. Preferably, the intersection point of the fin edges form a radius no greater than around 0.005 inches.

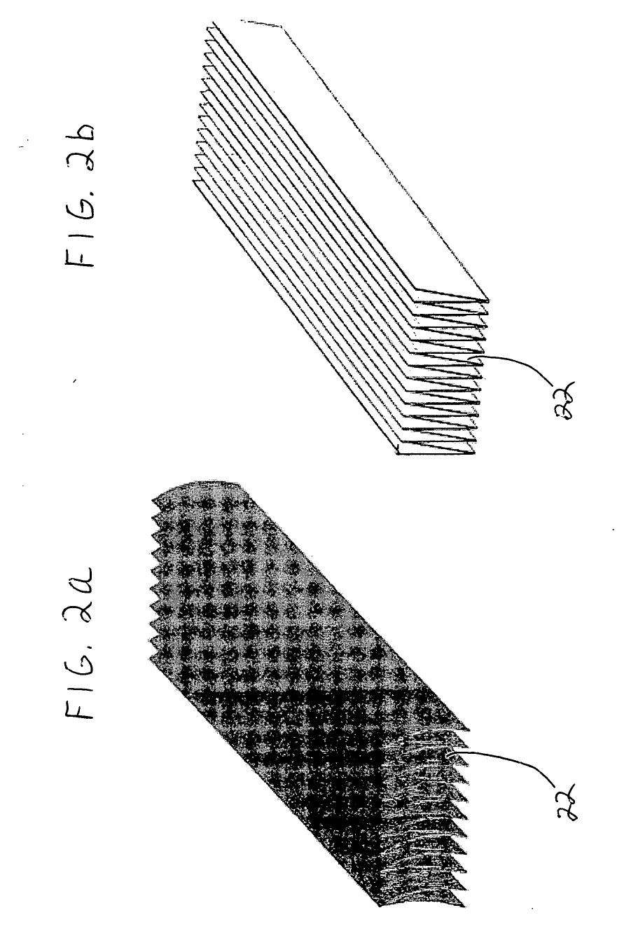

FIG. 2 a illustrates one embodiment of a wicking structure where the folded fins 22 form sharp contoured grooves for easy insertion into the housing 12 during assembly. In an alternative embodiment, such as that shown in FIG. 2b, the folded fins 22 define straight V-shaped grooves. Many other variations are possible.

Referring again to FIG. 1, the heat pipe 10 further includes a working fluid 26 such as water, methanol, ammonia, acetone or ethanol to channel along the folded fins 22. Welds or quick-disconnects (not shown) disposed at each end of the housing prevent the fluid from escaping the assembly. The fluid is vacuum sealed within the housing.

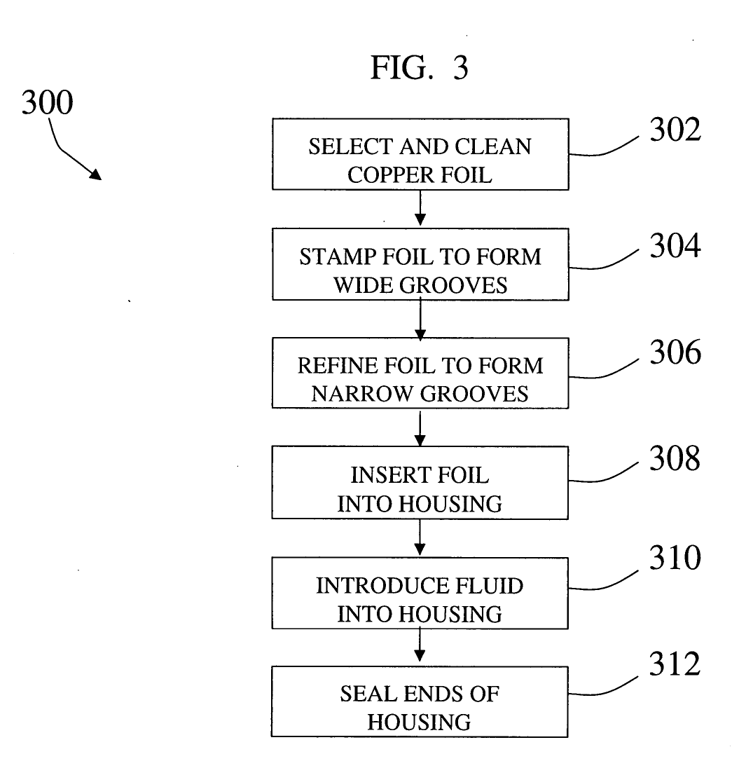

Referring now to FIG. 3, fabrication of the heat pipe 10 is accomplished via straightforward steps that define a unique low-cost process, generally designated 300. First, a suitable piece of thin copper foil is selected and cleaned, at step 302, to remove surface impurities that might affect fluid flow. Next, the foil is stamped, at step 304, to form relatively wide ninety-degree grooves. The grooves are then further refined, at step 306, to form narrow vertices having angles on the order of from ten to fifteen degrees. Once the copper foil is properly pleated, it is then inserted into the hollow housing 12, at step 308. Fluid is then introduced into the housing, at step 310, and sealed therein by capping the ends of the housing, at step 312. The sealing process may be accomplished by welding or mounting quick-disconnects to the condenser and evaporator ends.

In operation, the heat pipe described herein provides enhanced thermal conductivity due to the corrugated wick 20. This is directly due to the narrowly defined vertices 24 that enable the wicking structure to transport the fluid 26 in an improved manner consistent with wedge capillary theory. In general, wedge capillary theory asserts that based on the wetting angle of a fluid, two plates can be made to meet at a certain small critical angle which will transport a column of fluid asymptotically towards an infinite height. Based on this theory, I have discovered that by employing folded fins having vertices that define angles of between ten to fifteen degrees, the wicking action on the fluid may be maximized while preserving sufficiently wide pathways through the heat pipe 10 for vapor flow.

The enhanced performance of the heat pipe enables its successful implementation for automatic test equipment (ATE) applications, where the evaporator may often find itself above the condenser. In such a situation, the wicking action of the wick needs to be adequate to draw fluid from the condenser to the evaporator against gravity, and still maintain a cycle time sufficient to provide acceptable heat transfer.

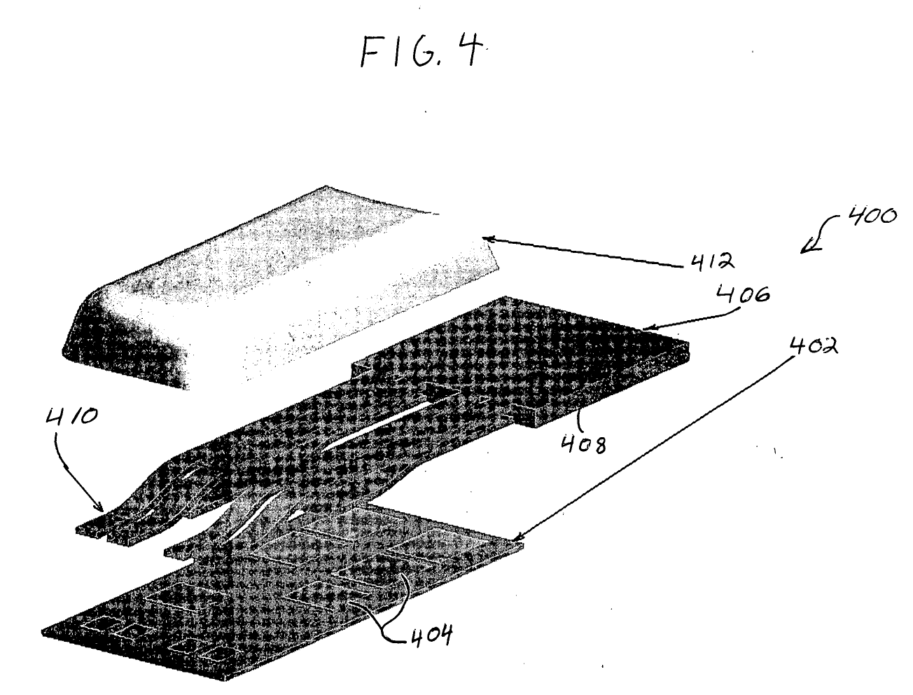

In one application, and referring now to FIG. 4, one embodiment of the heat pipe 12 is employed in a multi-chip module (MCM) 400. The MCM includes a substrate 402 that mounts a plurality of integrated circuits (ICs) 404. A heat pipe assembly 406 thermally contacts the ICs to provide a low cost cooling mechanism.

Further referring to FIG. 4, the heat pipe assembly comprises a rectangular heat sink plate 408 having one end formed with a plurality of heat pipe fingers 410. Each of the heat pipe fingers are formed consistent with the construction described above including the wedge capillaries. The distal evaporator ends of the heat pipes are contoured to allow for direct thermal coupling to the bare IC dies 404. A protective lid 412 covers the MCM assembly while exposing the heat sink plate for coupling to a liquid cooled cold plate (not shown).

In operation, as the ICs heat up due to power dissipation, the evaporator ends of the heat pipe fingers heat up, causing vaporization of the working fluid at that end. The pressure gradient developed inside the heat pipe forces the vapor through the folded fin channels, away from the evaporator end, to the condenser end. The vaporized fluid then condenses, with the heat thereupon transported to the heat sink plate via conduction. The cold plate module (not shown) further draws heat away from the heat sink plate to a high capacity liquid cooling system to complete the cooling process.

Those skilled in the art will recognize the many benefits and advantages afforded by the present invention. Of significant importance is the use of a corrugated wick that operates in accordance with wedge capillary theory to provide enhanced wicking action of condensed fluid. Additionally, the structure of the wicking structure enables a low-cost fabrication technique to further reduce cooling costs.

Having thus described several aspects of at least one embodiment of the heat pipe herein, it is to be appreciated that various alterations, modifications, and improvements will readily occur to those skilled in the art.

For example, while two specific corrugated wicks were described and illustrated herein, it is to be understood that a variety of materials and shapes may be employed consistent with the wedge capillary principles described herein for use with the heat pipe to achieve the improved heat transport capabilities. Further, although specific heat pipe shapes and sizes were presented herein as examples, a wide variety of dimensional possibilities exist depending on the application.

What is claimed is:

1. A heat pipe comprising:
an elongated hollow housing having a condenser end and an evaporator end;
a corrugated wick disposed within the housing, the corrugated wick comprising a plurality of wedge-shaped capillaries extending from the condenser end to the evaporator end, the wedge-shaped capillaries comprising folded fins having angles between adjacent fins within the range of five to fifteen degrees; and
a liquid set in fluid communication with the corrugated wick.

2. A heat pipe according to claim 1 wherein:
the corrugated wick comprises a pleated copper sheet.

3. A heat pipe according to claim 1 wherein:
the housing comprises a rectangular tube.

4. A heat pipe according to claim 1 wherein:
the liquid comprises water.

5. A heat pipe according to claim 1 wherein:
the folded fins define V-shaped grooves.

6. A heat pipe according to claim 1 wherein:
the folded fins define contoured grooves.

7. A heat pipe according to claim 1 wherein:
the folded fins define grooves that form a corner radii no greater than 0.005 inches.

8. A multi-chip module assembly comprising:
a multi-chip module comprising a substrate and a plurality of integrated circuits disposed on the substrate;
a heat pipe assembly, the heat pipe assembly comprising
a heat sink,
a plurality of heat pipes disposed in thermal contact with the integrated circuits, each heat pipe comprising
an elongated hollow housing having a condenser end and an evaporator end;
a corrugated wick disposed within the housing, the corrugated wick comprising a plurality of wedge-shaped capillaries extending from the condenser end to the evaporator end; and
a liquid set in fluid communication with the corrugated wick.

9. A multi-chip module assembly according to claim 8 wherein:
the wedge-shaped capillaries comprise folded fins having angles between adjacent fins within the range of ten to fifteen degrees.

10. A multi-chip module assembly according to claim 8 wherein:
the corrugated wick comprises a pleated copper sheet.

11. A multi-chip module assembly according to claim 8 wherein:
the housing comprises a rectangular tube.

12. A multi-chip module assembly according to claim 8 wherein:
the liquid comprises water.

13. A multi-chip module assembly according to claim 9 wherein:
the folded fins define V-shaped grooves.

14. A multi-chip module assembly according to claim 9 wherein:
the folded fins define contoured grooves.

15. A method of directing fluid away from the condenser end of a heat pipe to an evaporator end, the method comprising the steps:
wicking the fluid from the condenser to the evaporator over a plurality of pleated fins having respective wicking angles within the range of ten to fifteen degrees.

16. A heat pipe comprising:
an elongated hollow housing having a condenser end and an evaporator end;
a fluid disposed within the housing; and
means for wicking the fluid from the condenser end to the evaporator end.

17. A heat pipe according to claim 16 wherein the means for wicking comprises:
a corrugated wick disposed within the housing, the corrugated wick comprising a plurality of wedge-shaped capillaries extending from the condenser end to the evaporator end.

18. A heat pipe according to claim 17 wherein:
the wedge-shaped capillaries comprise folded fins having angles between adjacent fins within the range of ten to fifteen degrees.

19. A heat pipe according to claim 17 wherein:
the corrugated wick comprises a pleated copper sheet.

20. A heat pipe according to claim 16 wherein:
the housing comprises a rectangular tube.

21. A heat pipe according to claim 16 wherein:
the liquid comprises water.

22. A heat pipe according to claim 18 wherein:
the folded fins define V-shaped grooves.

23. A heat pipe according to claim 18 wherein:
the folded fins define contoured grooves.
